(19) United States
(12) Patent Application Publication
(10) Pub. No.: US 2006/0144560 A1
(43) Pub. Date: Jul. 6, 2006

(54) Clip assembly structure for heat dissipating fins

(76) Inventor: Ruei-An Lo, Taipei (TW)

Correspondence Address: Hsiang Kang Enterprise Co., Ltd., P.O. Box No. 6-57, Junghe, Taipei, 235, TW

(21) Appl. No.: 11/028,190

(22) Filed: Jan. 4, 2005

(51) Int. Cl. H05K 7/20

(52) U.S. Cl. 165/80.3; 361/704

(57) ABSTRACT

A clip assembly structure for heat dissipating fins encompassing a plurality of mutually connected heat dissipating fins, which are disposed in a perpendicular and parallel fashion atop a heat dissipator base. Wherein a top edge and a bottom edge of a lamina of each of the heat dissipating fins is respectively transversally extended to form an upper and a corresponding lower connecting strip respectively. A number of locking holes are defined in the connecting strips, and a lock joint piece extends from an end of each of the locking holes. Moreover, a V-shaped catch hook is press punched in each of the lock joint pieces, and catch hooks of the lock joint pieces of a second heat dissipating fin clip within the respective locking holes of the first heat dissipating fin, thereby enabling mutual affixing and connection between each of the heat dissipating fins.

### BACKGROUND OF THE INVENTION

(a) Field of the Invention

The present invention relates to a clip assembly structure for heat dissipating fins, and more particularly to a heat dissipator applicable for use on a variety of chipsets or processors in a computer, wherein a structure between each of the heat dissipating fins mutually connects and affixes the heat dissipating fins. Moreover, the present invention has other characteristics that provide effectiveness to reduce manufacturing costs.

(b) Description of the Prior Art

High temperature is generated when a chipset or processor is running, and the faster the chipset or processor is running the higher the driving wattage, which results in higher temperature being generated. If the temperature of the chipset or the processor is too high, running operations are affected, and results in the computer crashing. Hence, a heat dissipator is necessarily disposed atop the chipset or the processor in order to resolve heat dissipation problems.

Structural configuration of a conventional heat dissipator uses the conventional manufacturing method of aluminum extrusion to form the heat dissipator. Machining of the aluminum is then carried out to produce appropriate dimensions for practical application that match dimensions of the chipset or the processor.

In addition to shortcoming of slow production, resulting in relatively high production costs of the aforementioned manufacturing method to produce the aluminum extruded heat dissipator, clearance between adjoining heat dissipating fins cannot be too small, otherwise a die would be unable to withstand pressure load during aluminum extrusion and crack, which thus indirectly results in restricting number of the heat dissipating fins that can be assembled together. The fewer the number of heat dissipating fins, thereby presenting a corresponding smaller heat dissipating area, the slower the speed of heat dissipation is. Furthermore, die sinking is necessary in order to manufacture the aluminum extruded heat dissipator, and as soon as the die is produced there is the problem of difficulty in modifying the die, thereby restricting dimensions allowed for the aluminum extruded heat dissipator.

The various shortcomings as described above have gradually made the conventional aluminum extruded heat dissipator unable to resolve the heat dissipation problems of the unceasingly increasing operating speeds of the chipset or the processor, thus, related industries have designed a structural configuration whereby a plurality of the heat dissipating fins are manufactured separately, and then assembled together.

Referring to FIG. 1, which shows a conventional structural configuration having a plurality of heat dissipating fins 1, 1′, wherein the heat dissipating fins 20, 20′ are manufactured separately, and then assembled together. Each of the heat dissipating fins 1, 1′ are respectively pressed to form a lamina. Furthermore, two lap joint pieces 2, 2′ are transversally extended from top edges of the heat dissipating fins 1, 1′ respectively, and connecting strips 3, 3′ are transversally extended from bottom edges of the heat dissipating fins 1, 1′ respectively. The lap joint pieces 2, 2′ and the connecting strips 3, 3′ are further punched to form locating holes 4, 4′ respectively, the upper and lower locating holes 4, 4′ being relatively positioned in the heat dissipating fins 1, 1′ respectively. Catch pieces 5, 5′ are further configured on an end of each of the locating holes 4, 4′ respectively.

The two heat dissipating fins 1, 1′ are adjacently disposed during assembly whereby the top lap joint pieces 2 and the connecting strip 3 of the heat dissipating fin 1 are superpositioned on the other heat dissipating fin 1′, and clips into respective locating holes 4′ of the lap joints 2′ and the connecting strips 3′ of the heat dissipating fin 1′ by means of the catch pieces 5, thereby affixing position of the two heat dissipating fins 1, 1′, and completing assembly thereof. Additional heat dissipating fins are similarly assembled one by one, thereby completing assembly of a plurality of heat dissipating fins to form the heat dissipator.

Problems of aluminum extruded heat dissipator production and heat dissipation efficiency can be resolved through the plurality of heat dissipating fins being separately manufactured and assembled according to the aforementioned prior art means. However, structural configuration of the heat dissipator is still short of ideal, primarily because each of the catch pieces 5 are pressed to form an inverse U-shape (if the upper catch pieces 5 are formed as inverse U-shapes, then the lower catch pieces 5 are U-shaped, opposite to that of the upper catch pieces 5), and use two vertically oriented side edges 6 to clip into the respective locating holes 4′ of the other adjacent heat dissipating fin 1′. If angles of the two vertically oriented side edges 6 slightly deviate from the vertical position (for instance, the angles are spread externally forming an inverse V-shape), then clipping into the locating holes 4 is difficult or the clip fastening is insufficiently tight after clipping the vertically oriented side edges 6 within the locating holes 4, thereby resulting in loosening of the heat dissipating fins after assembly. In addition, the two lap joint pieces 2 are independently transversally extended from the top end edge of the heat dissipating fin 1, and easily deform when being press stamped, which results in additional loosening of the assembled plurality of heat dissipating fins.

Furthermore, because of the two lap joint pieces 2 configured on the top edge of the heat dissipating fin 1 and the connecting strip 3 at the bottom edge, thus orientation needs to be taken into account during assembly whereby the upper and lower ends cannot be reversed, thereby resulting in relative wastage of man-hours during assembly. Hence, there is a need for improvement in prior art.

### SUMMARY OF THE INVENTION

The present invention provides a clip assembly structure for heat dissipating fins encompassing a plurality of mutually connected heat dissipating fins, which are disposed in a perpendicular and parallel fashion atop a heat dissipator base. Wherein a top edge and a bottom edge of a lamina of each of the heat dissipating fins is respectively transversally extended to form an upper and a corresponding lower connecting strip respectively. A number of locking holes are defined in the connecting strips, and a lock joint piece extends from an end of each of the locking holes. Moreover, a V-shaped catch hook is press punched in each of the lock joint pieces, and catch hooks of the lock joint pieces of a second heat dissipating fin clip within the respective locking holes of the first heat dissipating fin, thereby enabling mutual affixing and connection between each of the heat dissipating fins.

Furthermore, the present invention can be implemented with catch hooks that are U-shaped or flat-bottomed U-shaped in addition to the aforementioned V-shaped catch hooks.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows an exploded elevational view of a conventional assembly of heat dissipating fins.

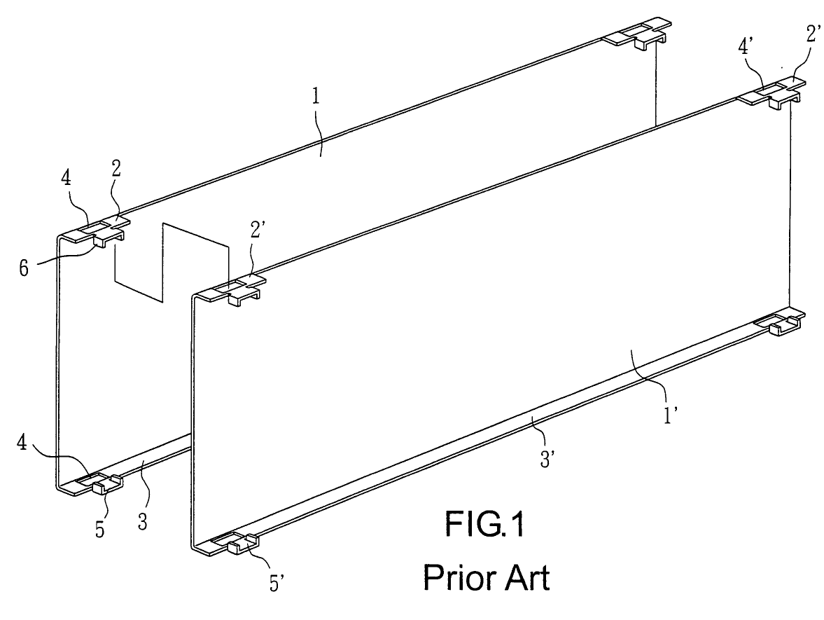

FIG. 2 shows an elevational view of heat dissipating fins disposed on a heat dissipator base, which is mounted on a processor, according to the present invention.

FIG. 3 shows an exploded elevational view of a structural assembly of the heat dissipating fins according to the present invention.

FIG. 4 shows a schematic view of an assembly of a plurality of the heat dissipating fins according to the present invention.

FIG. 5 shows side views of embodiments of catch hooks according to the present invention.

### DETAILED DESCRIPTION OF THE PREFERRED EMBODIMENTS

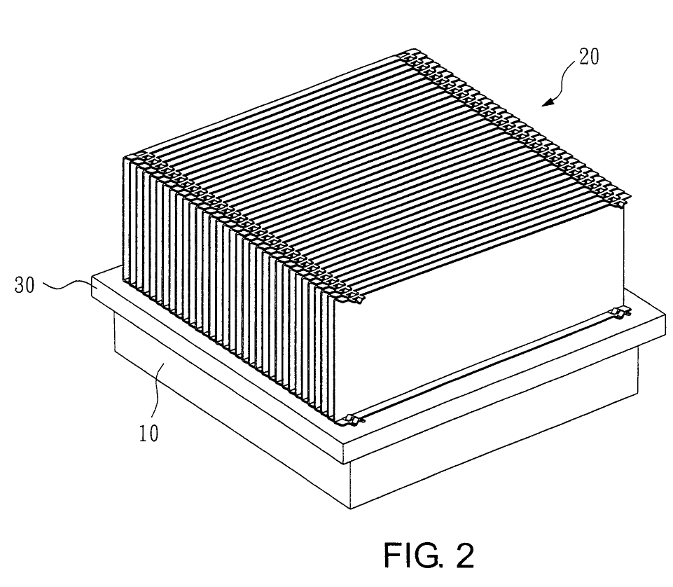

Referring to FIG. 2, which shows a heat dissipator encompassing an assembled structure of heat dissipating fins according to the present invention. The heat dissipator is particularly applicable for use with various chipsets or a processor 10 as used in a computer, and is primarily structured to comprise a plurality of mutually connected heat dissipating fins 20, 20′ disposed in a perpendicular and parallel fashion atop a heat dissipator base 30.

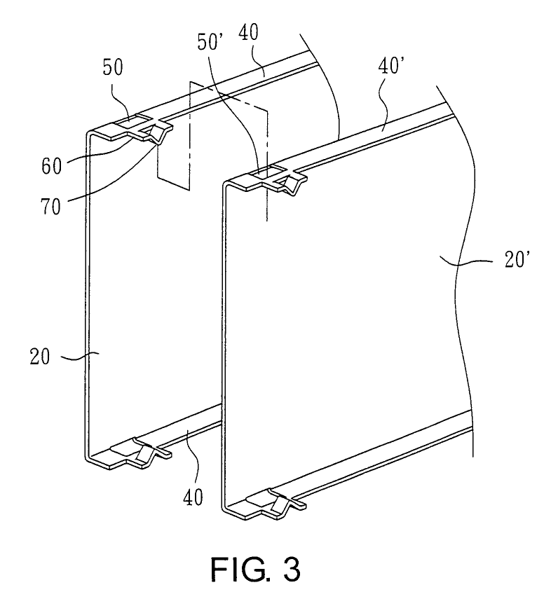

Referring to FIG. 3, which shows the plurality of heat dissipating fins 20, 20′ of the present invention, wherein a top edge and a bottom edge of a lamina of the heat dissipating fin 20 is respectively transversally extended to form an upper and a corresponding lower connecting strip 40.

Using the heat dissipating fin 20 on a left side of FIG. 3 as an exemplary example, a number of locking holes 50 are defined in the connecting strips 40, and a lock joint piece 60 extends from an end of each of the locking holes 50. Moreover, V-shaped catch hooks 70 are respectively press punched in each of the lock joint pieces 60 (orientation of each of the lower catch hooks 70 is reverse that of the upper catch hooks 70, and forms an inverse V-shape), and clip exactly within respective locking holes 50′ of a connecting strip 40′ of another heat dissipating fin 20″.

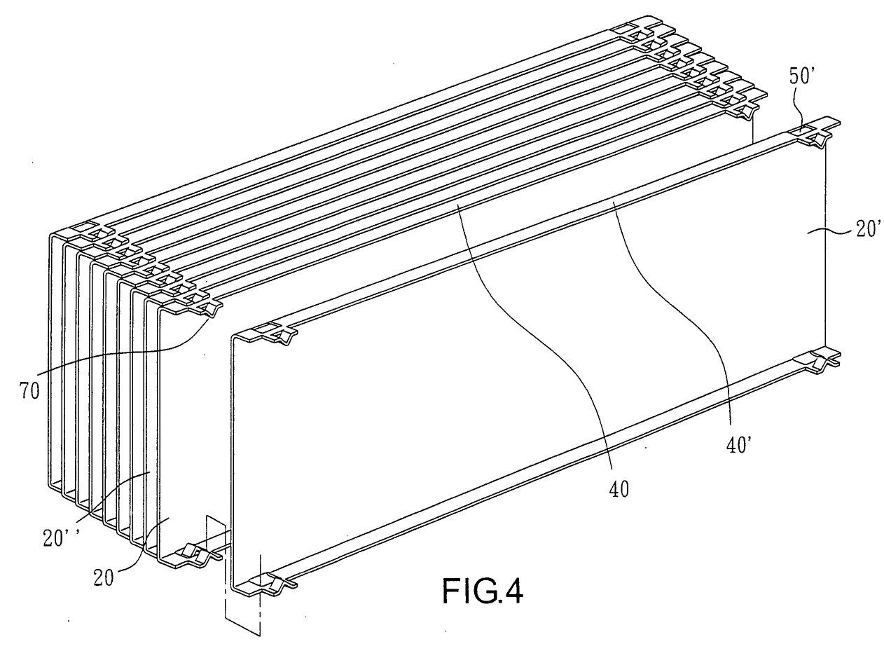

Referring to FIG. 4, which shows the aforementioned catch hooks 70 of the connecting strips 40 of the example heat dissipating fin 20 clipped within the locking holes 50′ of the connecting strips 40′ of the other heat dissipating fin 20′, thereby assembling the two heat dissipating fins 20 and 20′. Additional heat dissipating fins 20″, and so on, are similarly assembled and connected one after another and affixed to the aforementioned heat dissipator base 30 of FIG. 2 whereby assembly of the entire heat dissipator is completed.

The greatest dissimilarities between the present invention and conventional prior art can be found in the connecting strips 40, the locking holes 50, the lock joint pieces 60 and the catch hooks 70 of the heat dissipating fin 20, which realize an upper and lower inverse corresponding structural configuration whereby the structural configuration is identical when the heat dissipating fin 20 is inversely disposed. With such a structural configuration, when each of the heat dissipating fins 20, 20′ are being assembled, it is not necessary to make allowances as to whether the heat dissipating fins are upside down or not, thus expediting assembly of the heat dissipating fins 20, 20′. In addition, the catch hooks 70 of the present invention are V-shaped, (taking the upper catch hooks 70 as example), and compared to an inverse U-shaped catch piece of conventional prior art, even if relative positions of the catch hooks 70 are slightly shifted, the catch hooks 70 can still be very easily clipped within the respective locking holes 50′. Moreover, the lock jointed structural configuration is relatively more stable.

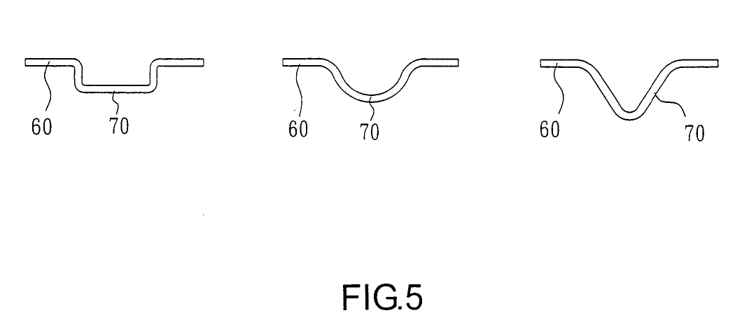

Referring to FIG. 5, the aforementioned catch hooks 70 can be U-shaped or flat-bottomed U-shaped in addition to being V-shaped, thereby forming further viable embodiments that equally provide advantages of rapid lock jointing assembly and stability.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A clip assembly structure for heat dissipating fins comprising a plurality of mutually connected heat dissipating fins, which are disposed in a perpendicular and parallel fashion atop a heat dissipator base, wherein a top edge and a bottom edge of a lamina of each of the heat dissipating fins is respectively transversally extended to form an upper and a corresponding lower connecting strip respectively; a number of locking holes are defined in the connecting strips, and a lock joint piece extends from an end of each of the locking holes, moreover, a V-shaped catch hook is press punched in each of the lock joint pieces, catch hooks of the lock joint pieces of a second heat dissipating fin clip within the respective locking holes of the first heat dissipating fin, thereby enabling mutual affixing and connection between each of the heat dissipating fins.

2. The clip assembly structure for heat dissipating fins as described in claim 1, wherein the catch hooks are U-shaped.

3. The clip assembly structure for heat dissipating fins as described in claim 1, wherein the catch hooks are flat-bottomed U-shaped.
